(19) United States
(12) Patent Application Publication
(10) Pub. No.: US 2013/0176687 A1
(43) Pub. Date: Jul. 11, 2013

(54) EXPANDABLE CONTROL UNIT AND CONTROL SYSTEM FOR INDUSTRIAL APPLICATIONS

(71) Applicants: Vinson Epperson, Charlottesville, VA (US); Kenneth Crawford, Charlottesville, VA (US); David Elliott, Charlottesville, VA (US); Harald Gruber, Augsburg (DE); Peter Missel, Augsburg (DE); Thomas Shannon, Charlottesville, VA (US); Bernardo Anger, Charlottesville, VA (US)

(72) Inventors: Vinson Epperson, Charlottesville, VA (US); Kenneth Crawford, Charlottesville, VA (US); David Elliott, Charlottesville, VA (US); Harald Gruber, Augsburg (DE); Peter Missel, Augsburg (DE); Thomas Shannon, Charlottesville, VA (US); Bernardo Anger, Charlottesville, VA (US)

(21) Appl. No.: 13/345,055

(22) Filed: Jan. 6, 2012

(51) Int. Cl. H05K 7/00

(52) U.S. Cl. 361/735

(57) ABSTRACT

A control unit for industrial applications is provided comprising a first compute box having a first microprocessor and being configured to run at least one first operating system. A second compute box may also be provided having a second microprocessor and being configured to run at least one second operating system. The first and second operating systems may be the same or different. The compute boxes may be mechanically coupled together or connected via one or more copper or fiber-optic cables, for example. Additional compute boxes may be added to expand the capabilities of each control unit. An integrated or detachable display may also be added. A control system for controlling a plurality of local input and output drops or devices is also provided. The control system includes a plurality of control units that may be distributed around an industrial installation and capable of data transfer between each control unit.

### BACKGROUND OF THE INVENTION

1. Field of the Invention

The field of the invention relates to control systems generally, and more particularly, to certain new and useful advances in expandable control systems for industrial applications, of which the following is a specification.

2. Description of Related Art

Today, most industrial control systems include an arrangement of individual control modules plugged into a fixed backplane, mounted within a cabinet, and connected to input and output (I/O) modules in one or more locations around an industrial installation or manufacturing facility. As industrial processes get more complex and the need for distributed control systems increases, local input and output modules have been replaced with remote I/O drops, increasing the need for control modules to be physically located within the plant in multiple locations near the I/O drops.

When wiring directly to I/O modules within a control system having a fixed backplane, users must place the control system close to the equipment/machinery being controlled in order to minimize material costs (e.g. wire and conduit), installation costs (e.g. pulling the additional wire longer distances, engineering drawings, etc.), and maintenance costs (e.g. downtime due to cable cuts/shorts from things like vibration). When expanding I/O within an industrial application, more control systems will be needed closer to the machines, which increase installation costs due to the need for more control modules, and associated cabinets, etc. This adds both cost and complexity because multiple control systems must be interconnected and coordinated. Thus, expansion using current control systems with their fixed backplane structure can result in increased expense and inconvenience associated with the need for more rack/cabinet space, because most of the input and output modules must be located closer to the equipment that is being monitored and controlled.

Thus, there is a need for a control system that takes into account a system's need for distributed I/O, ease of expansion, and increase in control system computing power, without a large increase in footprint. In addition, there is a need for control systems to have more modular capabilities to accommodate the data capture and high-speed computing needs of industrial applications as input and output monitoring and control requirements change and grow.

### BRIEF SUMMARY OF THE INVENTION

The present disclosure describes embodiments of a control unit which can be expanded into larger distributed control systems for industrial applications. The architecture of the control unit of the present invention provides the flexibility to scale or increase the computing power and diversify the control capabilities within individual control units as well as scale out to larger control systems by connecting multiple control units. Each compute box of the present invention may be configured to run real time operating systems with capabilities such as user logic execution, remote I/O handling, network protocol processing, and motion servo and drive control, etc. In addition, each compute box may also be configured to run standard PC graphical user interface (hereinafter “GUI”) operating systems. The compute boxes may be connected together along a high speed communication bus (e.g. Gigabit Ethernet bus Peripheral Component Interconnect, PCI-Express, etc.). The computational load of applications such as control system logic, display, trending, etc. may be spread out between control units in a distributed control system or between compute boxes in a single unit of the present invention.

The control units of the present invention may include one or more compute boxes. One embodiment of a control unit of the present invention includes two compute boxes. In this embodiment, a first compute box is provided having a first microprocessor. The first compute box is configured to run a first operating system. A second compute box may also be provided having a second microprocessor. The second compute box is configured to run a second operating system. The first and second operating systems may be the same or different. For example, the first operating system may be a general purpose operating system (hereinafter GPOS) such as Microsoft Windows (e.g. XP, Win 7, Win 8), or Linux, etc. The second operating system may be a real-time operating system (hereinafter RTOS) such as VxWorks, QNX, LynxOS, or OpenRTOS etc. For safety-related applications, it may be advantageous to use a safety certified (e.g. IEC 61508) version of a RTOS. In another embodiment, either the first or the second compute box is configured to run “bare metal”, i.e., directly on the processor without an operating system. One or more of the compute boxes may also have a multi-core processor, where multiple operating systems are running within a single compute box, each operating system being run on a different core of the microprocessor.

The first compute box and the second compute box are adapted to be mechanically coupled or physically mounted together. For example, the compute boxes may be layered one on top of the other and secured by a screw, and/or mated together such that the upper surface of the first compute box is adjacent to the bottom surface of the second compute box or vice versa. Any known means of mechanical coupling can be used. When coupled, the first compute box and the second compute box are capable of transferring information between each other along a high speed common communication bus, such as a Peripheral Component Interconnect Express (hereinafter “PCIe”) bus, Gigabit Ethernet bus, etc. In addition to PCIe, the compute boxes can also be connected via a Gigabit Ethernet connection.

The first and second compute boxes are connected together in a peer-to-peer relationship and are not in a master-slave relationship. The first microprocessor and the second microprocessor can be adapted to permit computational load sharing.

The control unit may further include an optional display box for displaying information, on a display screen and/or via LEDs on the face of the display box, aggregated from the first compute box and the second compute box. The display box may be a standalone component which is capable of being mechanically coupled to the first control unit. The display box may also be detachable from the control unit. Alternatively, the display box may be integrated into one of either the first or the second compute box.

The control unit of the subject invention may be expanded to include one or more additional compute boxes which are adapted to be capable of being mechanically coupled to the other boxes as described above, and may also communicate with the first and second compute boxes along a common communication bus or network connection, such as Ethernet. For example, a third compute box having its own processor can also be added and be configured to run a third operating system, the operating system being the same or different than either the first or the second operating systems. While the compute boxes are capable of being mechanically coupled, they may also be wired together to facilitate box-to-box communication, without being mechanically connected. A mounting plate may also be coupled to the control unit to facilitate mounting of the control unit to a cabinet or wall, as desired.

The present invention also provides a control system for an industrial installation comprising a plurality of control units for controlling a plurality of local input and output drops in an industrial installation. In one embodiment, each of the plurality of control units are distributed around the industrial installation and wired together. Each of the plurality of control units may comprise at least one first compute box having a first microprocessor and being configured to run a first operating system and may also include a second compute box having a second microprocessor and being configured to run a second operating system. The first compute box and the second compute box are adapted to be mechanically coupled. The first compute box and the second compute box are also capable of transferring information between each other along a high-speed Ethernet connection or along a high-speed serial communication bus, such as PCIe, when mechanically coupled. The compute boxes may also be wired together to facilitate box-to-box communication when uncoupled.

In one embodiment, the control system further comprises one or more display boxes for displaying information aggregated from the first compute box and the second compute box within at least one of the plurality of control units. The display box is capable of being mechanically coupled to at least one second compute box, and may be detachable as well. The display box may be capable of communicating with one or more of the control units. For example, the display unit may receive status information or transmit control signals to one or more of the plurality of control units that are distributed throughout the installation.

In one embodiment, the control system further comprises a master display screen for remotely displaying status information to a user. The display screen may be configured to display a graphical illustration of the overall status of various input and output drops throughout the industrial installation at a location away from the control units.

Other features and advantages of the disclosure will become apparent by reference to the following description, taken in connection with the accompanying drawings.

### BRIEF DESCRIPTION OF THE SEVERAL VIEWS OF THE DRAWINGS

Reference is now made briefly to the accompanying drawings, in which:

FIG. 1a is an exploded view of a control unit according to an embodiment of the present invention;

FIG. 1b is a perspective view of the control unit of FIG. 1 with the display, compute boxes and mounting plate mechanically coupled together;

FIG. 2 is an exploded view of the extendible feature of a control unit according to another embodiment of the present invention, having N number of compute boxes and a display box; and

FIG. 3 is a graphical illustration of an industrial installation having a plurality of control units distributed throughout the installation.

Like reference characters designate identical or corresponding components and units throughout the several views, which are not to scale unless otherwise indicated.

### DETAILED DESCRIPTION OF THE INVENTION

The present disclosure describes embodiments of a control unit which can be expanded into a larger distributed control system for industrial applications. The architecture of the control unit of the present invention provides the flexibility to increase the computing power and diversify the control capabilities within individual control units as well as scale out to larger control systems by connecting multiple control units.

Each compute box of the present invention may be configured to run RTOSs with capabilities, such as user logic execution, remote I/O handling, network protocol processing, motion servo and drive control, etc. Compute boxes may also be configured to run standard PC GUI OSs such as Microsoft Windows or Linux. This allows for off the shelf applications such as control system logic, display, trending, etc. to be spread out between control units in a distributed control system. A display box may also be provided. The display box may be detachable or integrated into one of the compute boxes, for displaying, transmitting or receiving info nation from one or more of the compute boxes. The display box may be a smart display box having its own microprocessor and running its own operating system, such as an Android operating system or the like.

The compute boxes and optional display box may be mechanically coupled together to form a control unit. One of the benefits and advantages of the mechanical architecture of the control units of the present invention is the reduced demand for horizontal and vertical footprint. In a conventional system, the horizontal and vertical space within a control cabinet of rack-mounted modules is difficult to minimize when expansion is desired, because each module must be mounted on the rack or fixed backplane. In contrast, the control units of the present invention can be expanded by mechanically coupling additional compute boxes along a depth direction (i.e. z-axis) of a cabinet. Because, the compute boxes of the present invention do not require a fixed backplane mounted within a cabinet, and are coupled along a depth direction, expansion can be implemented without increasing vertical and horizontal cabinet space. Furthermore, the compute boxes may alternatively be wired together, rather than mechanically coupled, giving users flexibility in terms of how the control units are housed within an industrial installation.

Additional boxes may also be added to the control unit of the present invention. For example, a box that provides additional network capabilities (e.g. copper, fiber, or SFPs) and/or PCIe ports may also be coupled, mechanically and/or electrically to a control unit of the present invention. There may also be additional boxes that enable direct connections to the control unit (e.g. local I/O input boxes etc.). These additional boxes may also share the common communication bus of the compute and display boxes.

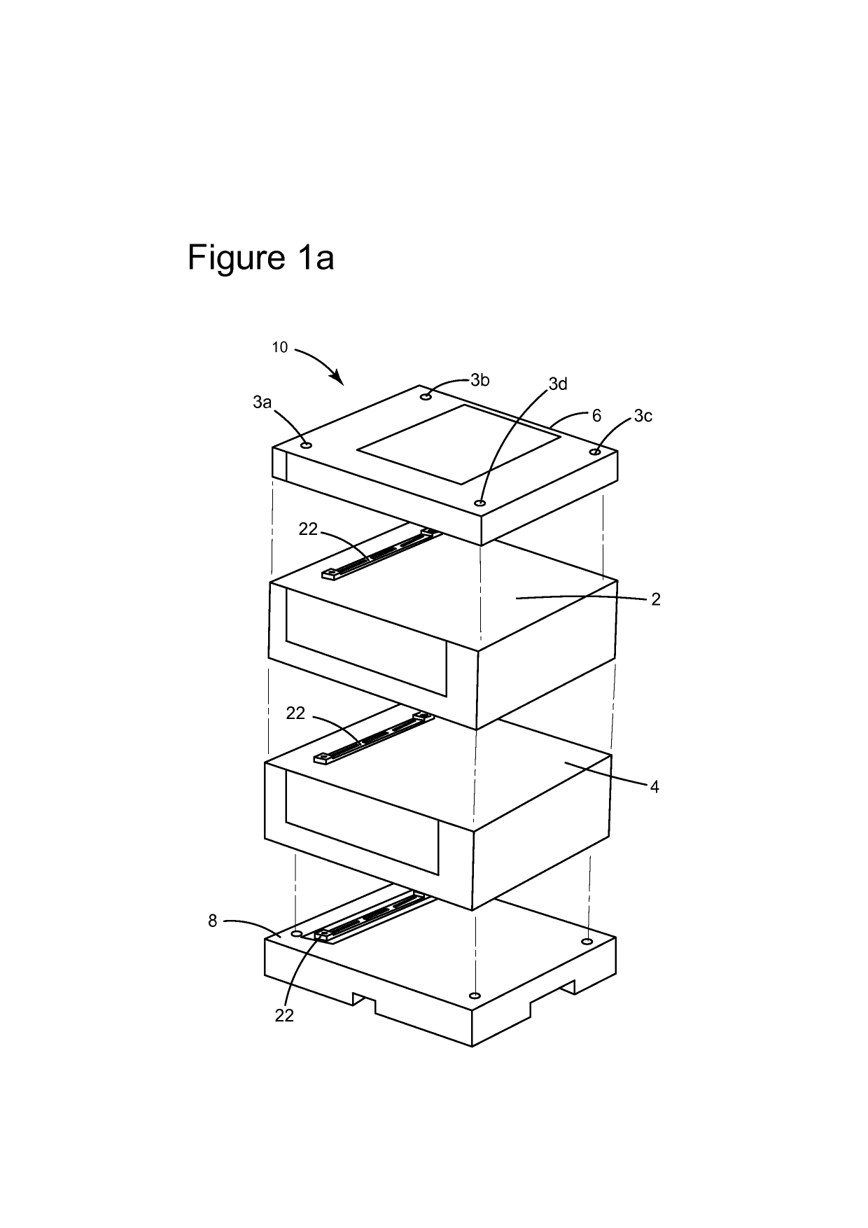

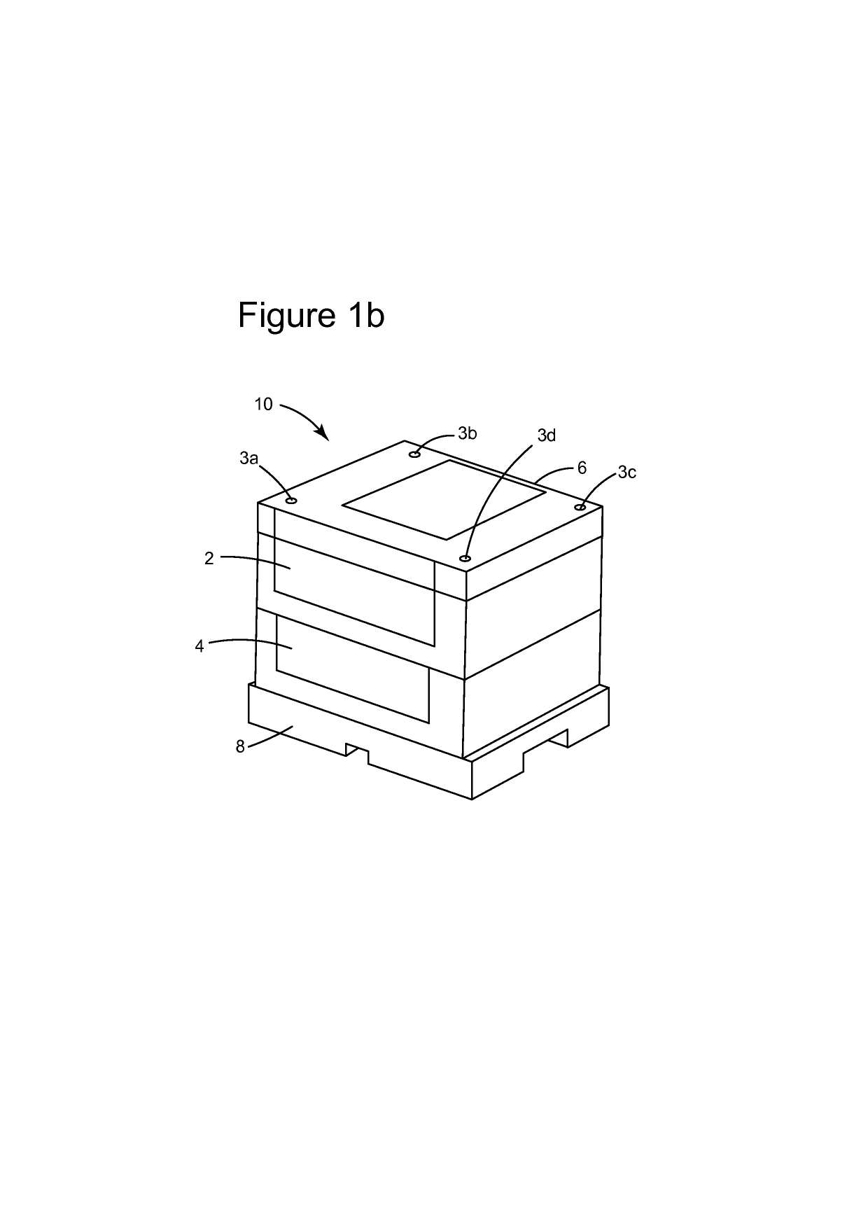

FIG. 1a is an exploded view of a control unit 10 for industrial applications according to an embodiment of the present invention. The control unit 10 includes compute box 2, compute box 4, an optional display box 6, and an optional mounting plate 8. FIG. 1b is a perspective view of the control unit 10 of FIG. 1 with the compute boxes 2 and 4, display box 6, and mounting plate 8 mechanically coupled together. In one embodiment, the compute boxes 2 and 4 are approximately 2 inches thick, 7.55 inches wide and 4.55 inches long; the display box 6 is approximately 0.65 inches thick, 7.55 inches wide and 4.55 inches long; and the mounting plate is approximately 0.7 inches thick, 9 inches wide, and 4.55 inches long. Typically, the dimensions of the compute boxes 2 and 4 are identical, however they may be different. The dimensions of the display box 6, in particular, the width and length of the display box 6 may be larger than those of the compute boxes 2 and 4 based on a desired size of the display screen provided on the display box 6. In a preferred embodiment, each compute box 2 and 4 weigh approximately three pounds, the stand alone display box 6 weighs approximately one pound, and the mounting plate 8 weighs approximately two pounds. In another embodiment, the weights of each of the aforementioned elements ranges within ten percent from the aforementioned approximate weights.

The compute boxes 2 and 4 are capable of being mechanically coupled together in a layered fashion such that the upper surface of compute box 2 is adjacent to the bottom surface of compute box 4. The display box 6 and the mounting plate 8 may be mechanically coupled in a similar fashion, as shown in FIG. 1b. The mechanical coupling may be implemented through one or more screws inserted around an outer surface of each of the components of the control unit. For example, FIG. 1a illustrates a number of screw holes 3a, 3b, 3c and 3d. The screw holes 3a-3d are provided around corresponding outer edges of compute box 2, compute box 4, display box 6, and mounting plate 8, such that one or more screws can be inserted along the axes, indicated by the dotted lines, in order to mechanically secure the boxes of the control unit 20 together. Other known methods may also be used to secure, interlock, snap-fit or mate the boxes together, such as grooves, connectors, clips, knobs, projections and the like. The display box 6 and compute boxes 2 and 4 may be configured so that they are capable of being coupled, but may also be detachable from each other.

Compute box 2, compute box 4, and display box 6 are capable of transferring information between each other along a common communication bus 22 when coupled. The mechanical coupling of the display box 6 and compute boxes 2 and 4 facilitates the connection of the common communication bus 22. The common communication bus 22 may provide necessary high speed communication signals such as PCIe, and Gigabit Ethernet. The compute boxes 2, and 4, and display box 6 may also be wired together using copper and/or fiber-optic cables, allowing box-to-box communication for data and computational load sharing purposes, even if they are not connected mechanically. The common communication bus 22 allows the display box 6 to interact using a services based mechanism and may be capable of communicating information to and from the box whether it is attached to the control unit via mechanical coupling or cabled together using wire(s). Compute boxes 2, and 4 are capable of driving the display box 6, which may be a smart display with its own processor. The display box 6 may be attached via industry standard interfaces such as DisplayPort, LVDS, HDMI, and DVI. Audio capabilities/support may also be provided by the control unit 20 such that a user is able to hear alerts based on a status and values of the I/O being monitored and controlled.

The compute boxes 2 and 4 may be configured to support the same hardware platforms and operating system or different hardware platforms or operating systems. For example, in one embodiment, compute box 2 is a programmable logic controller (PLC) with a VxWorks or similar operating system, and compute box 4 is a supervisory control and data (hereinafter SCADA) module with a Microsoft Windows, Linux or similar operating system. Alternatively, compute box 2 and compute box 4 may also have the same operating system.

Each compute box of the control units of the present invention, may utilize one or more microprocessor architectures (e.g. x86, PPC, ARM, etc.). For example, in one embodiment, compute box 2 and compute box 4 both have only one single microprocessor, and computational load sharing may take place between compute boxes 2 or 4. In another embodiment, either one or both of compute box 2 and the second compute box 4 has multiple microprocessor cores. This enables multiple operating systems to be run within a single compute box, one operating system on each core. For example, a quad-core microprocessor may be used for one or both of the compute boxes 2 and 4, such that a PLC operating system is running on one core, PROFINET is running on a second core, MS Windows is running on a third core and safety or motion is running on a fourth core. A hypervisor or Virtual Machine Manager (VMM) or the like may be utilized as an isolation mechanism so that each of the different operating systems on each microprocessor does not interfere with the other operating system, except via hypervisor supplied mechanisms.

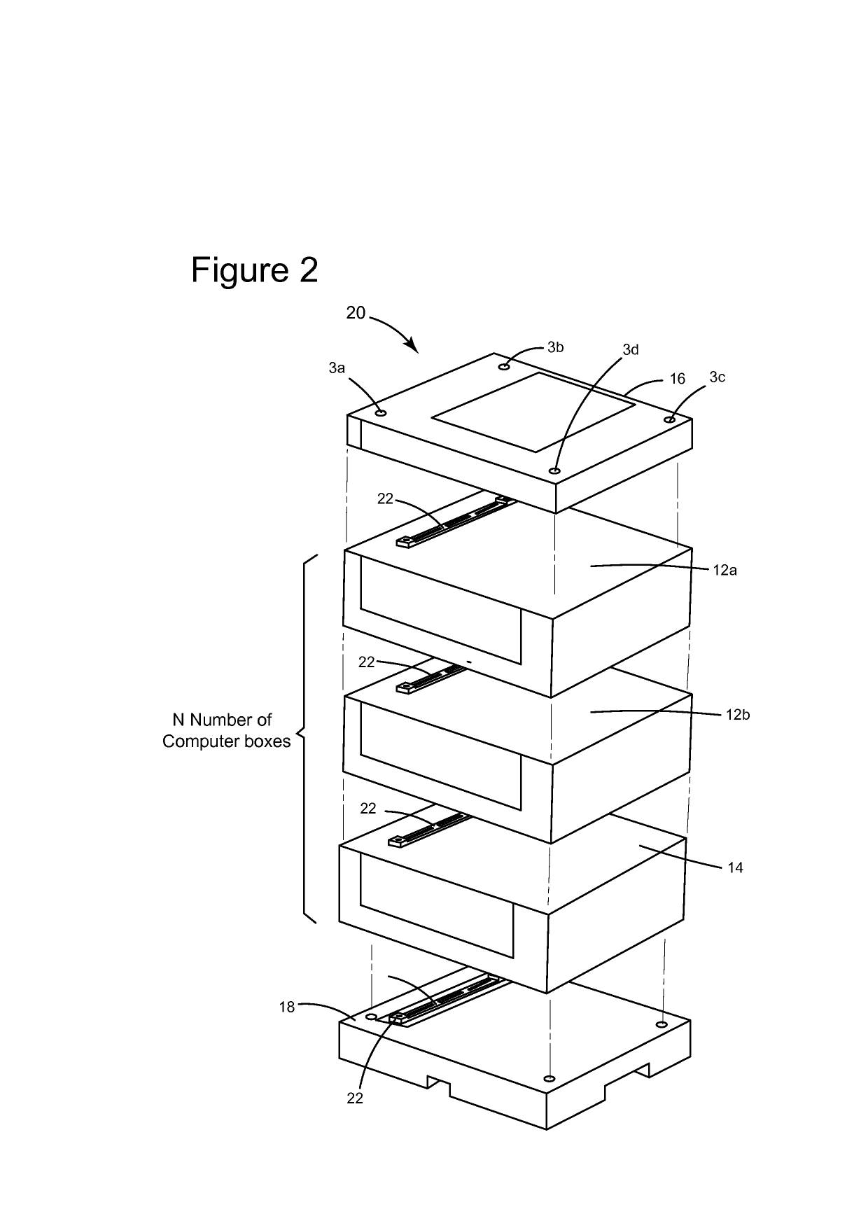

Turning to FIG. 2, an exploded view of a control unit according to another embodiment of the present invention is illustrated. In this embodiment, the control unit 20 may have N number of compute boxes, where N is greater than or equal to one. FIG. 2 illustrates an instance in which N=3. In this embodiment, compute box 14 may have serve as the supervisory control and data module with a corresponding operating system, whereas both compute boxes 12a and 12b may operate as programmable logic controllers having corresponding operating systems. Like control unit 10, control unit 20 may have an integrated or detachable display box 16 and a mounting plate 18, each of which are adapted to be mechanically coupled to the compute boxes 14, 12a and 12b. The compute boxes 12a, 12b and 14 of control unit 20 may also be configured having one or more microprocessor cores and may permit computational load sharing as described above with respect to control unit 10. The display unit may vary in size, and for example, may have larger dimensions relative to one or more of the control boxes within the control unit 20.

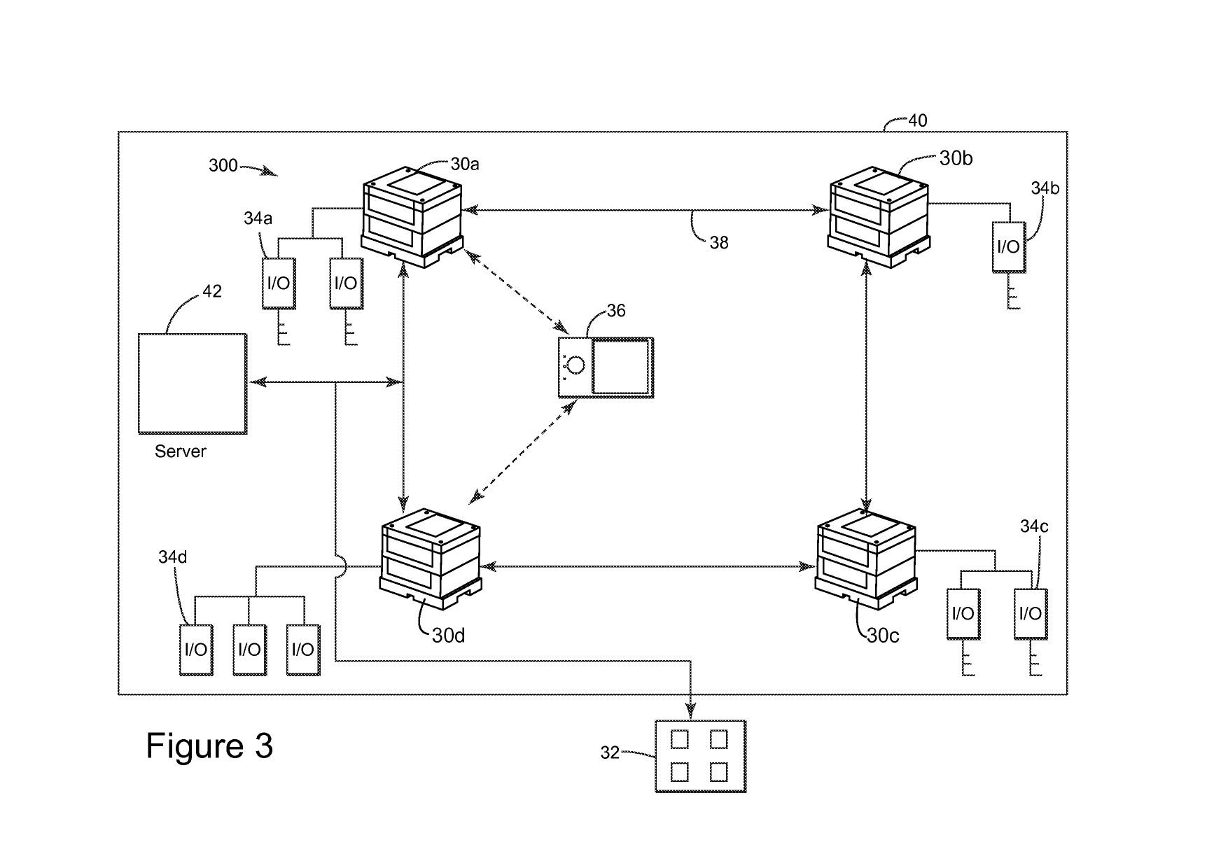

FIG. 3 is a graphical illustration of a control system 300 provided within an industrial installation 40 having a plurality of control units 30a, 30b, 30c and 30d. Each control unit 30a-30d is connected to a corresponding input/output drop or device 34a, 34b, 34c, and 34d present within the installation 40. The control system 300 can be clustered together or distributed around the installation 40, as shown in FIG. 3, and may be configured to support high-availability and safety applications through hardware and software redundancy. The control system 300 may have one or more display boxes 36. The display boxes 36 may be integrated into one of the compute boxes within the control units 30a-30d or may be standalone and/or detachable as indicated by the dotted lines shown in FIG. 3. The display box 36 may be directly connected to the same common communication bus 22 used for box-to-box communication between the compute boxes. Each display box 36 is capable of presenting information aggregated from one or more compute boxes of each of the control units 30a-30d.

Control units 30a-30d of the control system 300 may communicate with each other and with the distributed input/output drops 34a-34d spread throughout the installation via industrial Ethernet protocols and/or industrial fieldbuses 38. Control unit 300 may also include a server 42 for receiving, storing and transmitting data collected from control units 30a-30d. In one embodiment, the server 42 may be used to run a portion of analytics and/or data capture of the control units 30a-30d in order provide larger scale calculations and data storage. For example, one or more of the control units 30a-30d may run a historian collector and forward their collected data to a full historian which runs on the server 42. This may be advantageous if one or more of control units 30a-30d is of limited data storage capacity. For example, control unit 30a may have 32 gigabytes of storage, whereas the server 42 could have multiple terabytes of data storage capacity. In addition, due to potential thermal constraints within one or more of the control units 30a-30d, a server 42 could be used to house a more powerful processor relative to that of the compute boxes within the control units 30a-30d. As a result, the server 42 could be used to process data faster. A remote display 32 may also be connected to the server 42 and provided for illustrating status information of the entire control system 300 to a user located at a distance from the installation 40.

As used herein, an element or function recited in the singular and proceeded with the word “a” or “an” should be understood as not excluding plural said elements or functions, unless such exclusion is explicitly recited. Furthermore, references to “one embodiment” of the claimed invention should not be interpreted as excluding the existence of additional embodiments that also incorporate the recited features.

This written description uses examples to disclose the invention, including the best mode, and also to enable any person skilled in the art to make and use the invention. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

Although specific features of the invention are shown in some drawings and not in others, this is for convenience only as each feature may be combined with any or all of the other features in accordance with the invention. The words “including”, “comprising”, “having”, and “with” as used herein are to be interpreted broadly and comprehensively and are not limited to any physical interconnection. Moreover, any embodiments disclosed in the subject application are not to be taken as the only possible embodiments. Other embodiments will occur to those skilled in the art and are within the scope of the following claims.

What is claimed is:

1. A control unit for industrial applications comprising:
a first compute box having a first microprocessor and being configured to run a first operating system;
a second compute box having a second microprocessor and being configured to run a second operating system;
wherein the first compute box and the second compute box are adapted to be mechanically coupled, and
wherein the first compute box and the second compute box are capable of transferring information between each other along a common communication bus.

2. The control unit of claim 1, further comprising:
a display box for displaying information aggregated from the first compute box and the second compute box.

3. The control unit of claim 2, wherein the display box is integrated into the second compute box.

4. The control unit of claim 2, wherein the display box is adapted to be mechanically coupled to and detachable from the second compute box.

5. The control unit of claim 2, wherein a lower surface of the display box is positioned adjacent to an upper surface of the second compute box when mechanically coupled.

6. The control unit of claim 1, wherein the first operating system and the second operating system are different.

7. The control unit of claim 1, wherein the first operating system is a graphical user interface.

8. The control unit of claim 1, wherein the second operating system is a real-time operating system.

9. The control unit of claim 1, wherein an upper surface of the first compute box is positioned adjacent to a lower surface of the second compute box when mechanically coupled.

10. The control unit of claim 1, wherein the common communication bus is a peripheral component interconnect express bus.

11. The control unit of claim 1, wherein the common communication bus is a Gigabit Ethernet bus.

12. The control unit of claim 1, further comprising a mounting plate mechanically coupled to the first compute box and configured to facilitate mounting of the control unit.

13. The control unit of claim 1, wherein the first microprocessor and the second microprocessor are adapted to permit computational load sharing.

14. The control unit of claim 1, further comprising:
at least one third compute box having a processor and being configured to run a third operating system.

15. The control unit of claim 14, wherein the third operating system is the same as one of the first operating system and the second operating system.

16. The control unit of claim 14, wherein the at least one third compute box is adapted to be mechanically coupled to the first and second compute box.

17. A control system for an industrial installation comprising:
a plurality of control units for controlling a plurality of local input and output drops in an industrial installation, each of the plurality of control units being distributed around the industrial installation and wired together,
wherein each of the plurality of control units comprises:
a first compute box having a first microprocessor and being configured to run a first operating system;
a second compute box having a second microprocessor and being configured to run a second operating system;
wherein the first compute box and the second compute box are adapted to be mechanically coupled, and
wherein the first compute box and the second compute box are capable of transferring information between each other along a common communication bus.

18. The control system of claim 17, further comprising at least one display box for displaying information aggregated from the first compute box and the second compute box within at least one of the plurality of control units.

19. The control system of claim 18, wherein the at least one display box is capable of being mechanically coupled to at least one second compute box.

20. The control system of claim 17, wherein the at least one display box is capable of transmitting control signals to one or more of the plurality of control units.

21. The control system of claim 17, further comprising:
a display screen for remotely displaying status information based on the input and output drops throughout the industrial installation.
